(19) United States
(12) Patent Application Publication
(10) Pub. No.: US 2007/0108503 A1
(43) Pub. Date: May 17, 2007

(54) NON-VOLATILE MEMORY AND MANUFACTURING METHOD AND OPERATING METHOD THEREOF

(76) Inventors: Shi-Hsien Chen, Hsinchu City (TW); Yung-Chung Lee, Taipei County (TW); Hann-Ping Hwang, Hsinchu City (TW); Saysamone Pittikoun, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,498

(22) Filed: Mar. 30, 2006

(30) Foreign Application Priority Data
Nov. 11, 2005 (TW) 94139583

(51) Int. Cl. H01L 29/788

(52) U.S. Cl. 257/316

(57) ABSTRACT

A non-volatile memory is provided. At least two bit lines are disposed in a substrate. The two bit lines are arranged in parallel and extend in a first direction. A plurality of select gate structures is disposed on the substrate between the two bit lines respectively. The select gate structures are arranged in parallel and extend in a first direction. A gap is disposed between each two neighboring select gate structures. A plurality of control gate lines is disposed on the substrate and fills in the gaps between two neighboring select gate structures respectively. The control gate lines are arranged in parallel and extend in a second direction, which crosses the first direction. A plurality of charge storage layers is disposed between the select gate structures and control gate lines respectively.

### CROSS-REFERENCE TO RELATED APPLICATION

This application claims the priority benefit of Taiwan application serial no. 94139583, filed on Nov. 11, 2005. All disclosure of the Taiwan application is incorporated herein by reference.

### BACKGROUND OF THE INVENTION

1. Field of Invention

The present invention relates to a semiconductor device, and more particularly to a non-volatile memory and manufacturing method and operating method thereof.

2. Description of Related Art

Among various non-volatile memory products, electrically erasable programmable read only memory (EEPROM) has become a memory device widely adopted for use in personal computers and electronic equipment, as it has the advantages of access, read and erase data many times and the stored data will not disappear when the power is cut off.

The floating gate and control gate of the typical EEPROM are made of doped polysilicon. Also, to avoid the problem of error in reading of the data due to severe over-erase when the typical EEPROM is erased, a select gate is further disposed on sidewalls of the control gate and the floating gate, and above the substrate, to form a split-gate structure.

Furthermore, in the conventional technology, a charge trapping layer is adopted to replace the polysilicon floating gate, wherein the charge trapping layer includes, for example, a silicon nitride layer. The charge trapping layer sandwiched between two silicon oxide layers to form an oxide-nitride-oxide (ONO) composite layer, such as the EEPROM with a split-gate structure disclosed by U.S. Pat. No. 5,930,631. However, as the split-gate structure has a large memory cell size due to a large split-gate region being required, its memory cell size is higher than that of the EEPROM with stacked gates, thereby raising the problem that the device packing density cannot be further increased.

On the other hand, as the NAND array connects each memory cell in series, its packing density is higher than the NOR array. Therefore, if the split-gate flash memory cell is made into a structure of NAND array, the device can be made denser. However, the write and read procedure of the memory cell in the NAND array is more complicated, and as many memory cells are connected in series in the array, the read current of some memory cell will be smaller, however, the operating speed of the memory cell is slower and the efficiency of the device lower.

### SUMMARY OF THE INVENTION

In view of this, an object of the present invention is to provide a non-volatile memory and manufacturing method and operating method thereof. The non-volatile memory according to the present is capable of storing two-bit data in a single memory cell, and therefore the device packing density can be promoted.

Another object of the present invention is to provide a non-volatile memory capable of performing a program operation by source-side injection (SSI), and therefore the program speed and the memory efficiency can be promoted.

Another object of the present invention is to provide a simple and low cost method of fabricating a non-volatile memory.

The present invention provides a non-volatile memory, including a substrate, a plurality of select gate structures, a plurality of control gate lines, and a plurality of charge storage layers. At least two bit lines are disposed in the substrate, the two bit lines are arranged in parallel and extend in a first direction. A plurality of select gate structures is disposed on the substrate between the two bit lines respectively. The select gate structures are arranged in parallel and extend in a first direction. A gap is formed between each two neighboring select gate structures. A plurality of control gate lines is disposed on the substrate and fills in the gaps between two neighboring select gate structures respectively. The control gate lines are arranged in parallel and extend in a second direction, which crosses the first direction. The plurality of charge storage layers is disposed between the select gate structures and the control gate lines respectively.

In the above non-volatile memory, the charge storage layer includes a silicon nitride layer or a doped polysilicon layer.

In the above non-volatile memory, a first dielectric layer is disposed between the charge storage layer and the control gate line, wherein the first dielectric layer includes a silicon oxide layer. A tunneling dielectric layer is disposed between the charge storage layer and the substrate, wherein the tunneling dielectric layer includes a silicon oxide layer. A second dielectric layer is disposed between the charge storage layer and the select gate structure, wherein the second dielectric layer includes a silicon oxide layer.

In the above non-volatile memory, a plurality of isolation structures extending in a second direction is further disposed in the substrate between the control gate lines. The depth of the isolation structures is smaller than the depth of the two bit lines.

In the above non-volatile memory, each select gate structure includes a gate dielectric layer, a select gate and a cap layer. The gate dielectric layer is disposed over the substrate. The select gate is disposed over the gate dielectric layer. The cap layer is disposed over the select gate.

In the above non-volatile memory, a control gate dielectric layer is further disposed between the control gate line and the substrate.

In the non-volatile memory of the present invention, as no gap is formed between the memory cells, the packing density of the memory cells can be promoted. And, one-bit data can be stored in the charge storage layer between each select gate structure and each control gate line, that is, two-bit data can be stored in a single memory cell of the non-volatile memory of the present invention.

Furthermore, the gate length of the control gate can be determined by the gap length between the select gate structures, and therefore the gate length of the control gate can be reduced by reducing the gap length between the select gate structures, thereby promote the device packing density.

The present invention provides a method of fabricating the non-volatile memory. First, a substrate is provided, and at least two doped regions are formed in the substrate, wherein the two doped regions are arranged in parallel and extend in a first direction. A plurality of select gate structures is formed on the substrate between the two doped regions, wherein the select gate structures are arranged in parallel and extend in a first direction, and a gap is formed between two neighboring select gate structures. A plurality of spacers is formed on the sidewalls of the select gate structures after forming a first dielectric layer on the substrate, wherein the material of spacers includes a charge storage material. A plurality of control gate lines is formed over the substrate after forming a second dielectric layer over the substrate, wherein the control gate lines fill the gaps between the select gate structures, and the control gate lines are arranged in parallel and extend in a second direction, which crosses the first direction.

In the above method of fabricating the non-volatile memory, after the step of forming two doped regions in the substrate, a plurality of isolation structures is formed in the substrate, wherein the isolation structures extend in a second direction, and the depth of the isolation structures is smaller than that of the two doped regions.

In the above method of fabricating the non-volatile memory, the step of forming the select gate structures on the substrate includes forming a gate dielectric layer over the substrate; forming a first conductive layer over the gate dielectric layer; forming a cap layer over the first conductive layer; and patterning the cap layer, the first conductive layer and the gate dielectric layer.

In the above method of fabricating the non-volatile memory, the material of the spacers includes silicon nitride. The material of the first and second dielectric layers includes silicon oxide.

In the above manufacturing method of fabricating the non-volatile memory, the step of forming the control gate lines on the substrate is that: forming a second conductive layer on the substrate; and then patterning the second conductive layer. In the step of patterning the second conductive layer, it further includes removing part of the spacers to form a plurality of charge storage blocks. The material of the charge storage blocks includes silicon nitride or doped polysilicon.

In the manufacturing method of fabricating the non-volatile memory of the present invention, as the memory cells are connected in series with each other without a gap, the packing density of the memory array can be promoted. Compared with the conventional manufacturing method of fabricating the non-volatile memory, the manufacturing method of fabricating the non-volatile memory of the present invention is simpler, and therefore the manufacturing cost can be reduced.

The present invention provides an operating method of fabricating the non-volatile memory, which is useful for the memory array. The memory cell array includes: at least a first bit line and a second bit line extending in a row direction and disposed in parallel in the substrate; a plurality of select gate structures extending in the row direction and disposed in parallel on the substrate between the first bit line and the second bit line, with a gap being formed between each two neighboring select gate structures respectively; a plurality of control gates, disposed on the substrate and filled in the gaps between each two neighboring select gate structures; a plurality of charge storage layers, disposed between the select gate structures and the control gate lines respectively; a plurality of word lines, arranged in parallel in the row direction and connecting the gates of the select gate structures of the same row; a plurality of control gate lines, extending in a column direction, disposed in parallel on the substrate, and connecting the control gates of the same column; wherein two neighboring select gate structures, a control gate between two neighboring select gate structures, two charge storage layers between the select gate structures and the control gates respectively consist of a plurality of memory cells, and the neighboring memory cells share a select gate structure; the charge storage layer of each memory cell includes a first bit at the first bit line side and a second bit at the second bit line side. The method includes following operations.

For programming the non-volatile memory, a first voltage is to the selected control gate line connected to the selected memory cell; a second voltage is applied to the first bit line; a third voltage is applied to the second bit line; a fourth voltage is applied to the first selected word line at the first bit line side of the selected memory cell; and a fifth voltage is applied to other non-selected word lines, wherein the fourth voltage is higher than or equal to the threshold voltage of the select gate structures, the first and fifth voltages are higher than the fourth voltage, the third voltage is higher than the second voltage, so as to program the first bit by the Source-Side Injection (SSI).

In the above programming method, the first voltage is about 7 Volts, the second voltage is about 0 Volts, the third voltage is about 4.5 Volts, the fourth voltage is about 1.5 Volts, and the fifth voltage is about 7 Volts.

In the above programming method, a sixth voltage may be applied to the selected control gate line connected to the selected memory cell; a seventh voltage may be to the second bit line; an eighth voltage may be applied to the first bit line; a ninth voltage may be applied to the second selected word line at the second bit line side of the selected memory cell; and a tenth voltage may be applied to other non-selected word lines, wherein the ninth voltage is higher than or equal to the threshold voltage of the select gate structures, the sixth and tenth voltages are higher than the ninth voltage, and the eighth voltage is higher than the seventh voltage, so as to program the second bit by Source-Side Injection (SSI).

In the above programming method, the sixth voltage is about 7 Volts, the seventh voltage is about 0 Volts, the eighth voltage is about 4.5 Volts, the ninth voltage is about 1.5 Volts, and the tenth voltage is about 7 Volts.

For erasing the above non-volatile memory of the present invention, an eleventh voltage is applied to the control gate lines; a twelfth voltage is applied to the word lines; a thirteenth voltage is applied to the substrate; and floating the bit lines such that the electrons stored in the charge storage layer may be ejected into the substrate, wherein the voltage difference between the eleventh, twelfth voltages and the thirteenth voltage will cause FN tunneling effect to eject the electrons into the substrate.

In the above erasing method, the voltage difference is about −12 to −20 Volts. The eleventh voltage is 0 Volts, the twelfth voltage is 0 Volts, and the thirteenth voltage is about 12 Volts.

For reading the above non-volatile memory of the present invention, a fourteenth voltage is applied to the selected control gate line connected to the selected memory cell; a fifteenth voltage is applied to the first bit line; a sixteenth voltage is applied to the second bit line; a seventeenth voltage is applied to the first selected word line at the first bit line side of the selected memory cell; an eighteenth voltage is applied to other non-selected word lines; wherein in order to read the first bit, the seventeenth voltage is higher than the threshold voltage of the select gate structures, the fourteenth and eighteenth voltages are higher than the seventeenth voltage, and the fifteenth voltage is higher than the sixteenth voltage.

In the above reading method, the fourteenth voltage is about 5 Volts, the fifteenth voltage is about 2.5 Volts, the sixteenth voltage is about 0 Volts, the seventeenth voltage is about 2.5 Volts, and the eighteenth voltage is about 5 Volts.

In the above reading method, a nineteenth voltage may be applied to the selected control gate line connected by the selected memory cell; a twentieth voltage may be applied to the second bit line; a twenty-first voltage may be applied to the first bit line; a twenty-second voltage may be applied to the second selected word line at the side of the second bit line of the selected memory cell; a twenty-third voltage may be applied to other non-selected word lines; wherein in order to read the second bit, the twenty-second voltage is higher than the threshold voltage of the select gate structures, the nineteenth and twenty-third voltages are higher than the twenty-second voltage, and the twentieth voltage is higher than the twenty-first voltage.

In the above reading method, the nineteenth voltage is about 5 Volts, the twentieth voltage is about 2.5 Volts, the twenty-first voltage is about 0 Volts, the twenty-second voltage is about 2.5 Volts, and the twenty-third voltage is about 5 Volts.

In the above operation of the non-volatile memory of the present invention, programming is carried out by the Source-Side Injection (SSI) with a unit of a single bit of a single memory cell, and the erasing of the memory cell is carried out by using the FN tunneling effect. Therefore, the electron injection efficiency is higher, the operating current of the memory cell may be reduced, and the operating speed may also be increased. Also, the power consumption of the whole chip can be effectively reduced.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A shows a top view of a non-volatile memory according to a preferred embodiment of the present invention;

FIG. 1B shows a structural sectional view along line A-A′ in FIG. 1A.

FIG. 1C shows a structural sectional view along line B-B′ in FIG. 1A.

FIG. 2A is a schematic view of an example of a programming operation of the non-volatile memory according to the present invention.

FIG. 2B is a schematic view of another example of the programming operation of the non-volatile memory according to the present invention.

FIG. 2C is a schematic view of an example of a reading operation of the non-volatile memory according to the present invention.

FIG. 2D is a schematic view of another example of the reading operation of the non-volatile memory according to the present invention.

FIG. 2E is a schematic view of an example of an erasing operation of the non-volatile memory according to the present invention.

FIGS. 3A to 3E show a sectional flow chart of fabricating the non-volatile memory according to a preferred embodiment of the present invention.

FIG. 4 shows a sectional view of the non-volatile memory according to a preferred embodiment of the present invention.

### DESCRIPTION OF EMBODIMENTS

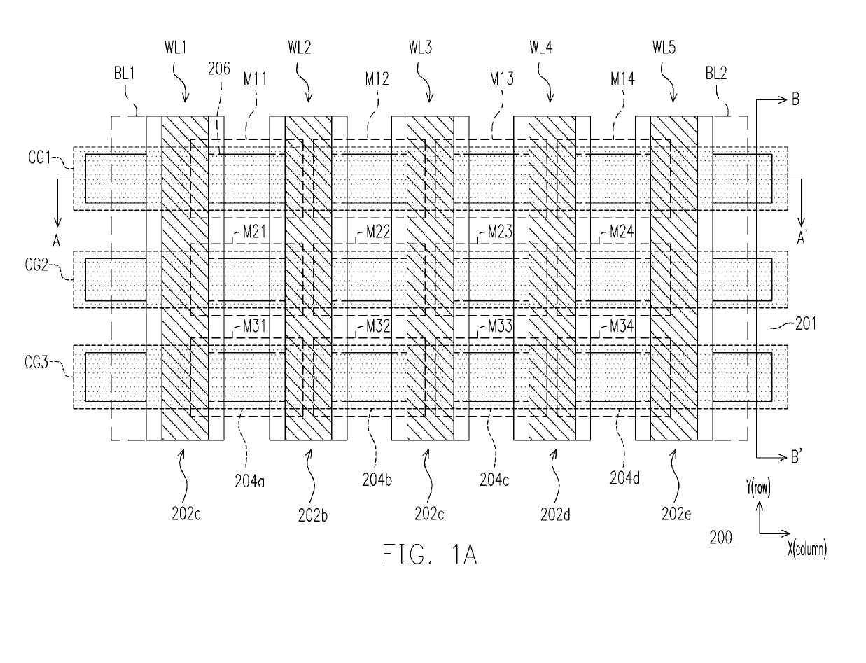

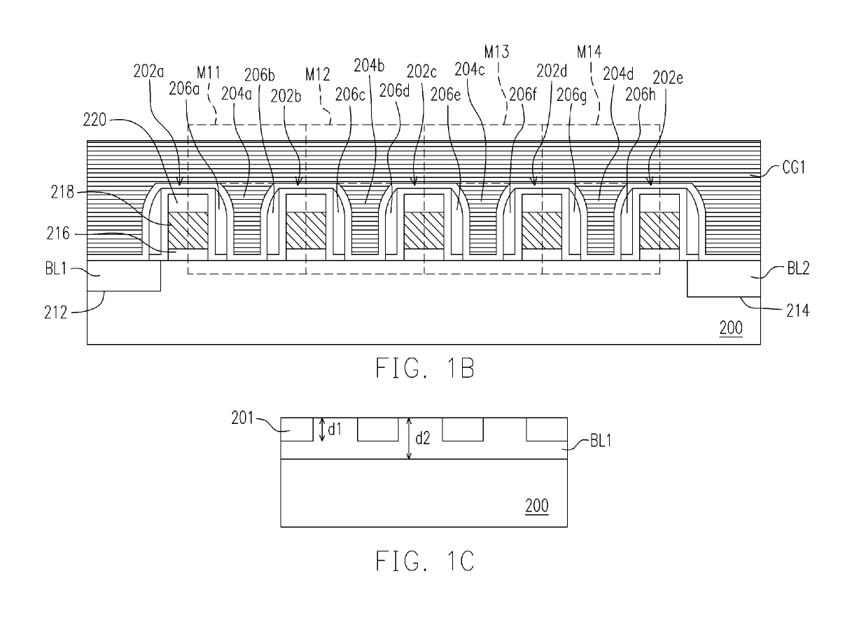

FIG. 1A shows a top view of a non-volatile memory according to a preferred embodiment of the present invention. FIG. 1B shows a structural sectional view along line A-A′ in FIG. 1A. FIG. 1C shows a structural sectional view along line B-B′ in FIG. 1A.

Referring to FIG. 1A, the non-volatile memory array of the present invention includes a substrate 200, a plurality of memory cells M11˜M34, a plurality of word lines WL1˜WL5, a plurality of control gate lines CG1˜CG3 and two bit lines BL1˜BL2.

The memory cells M11˜M34 are arranged in an array. The memory cells M11˜M34 of the same column are connected in series without a gap therebetween. For example, the memory cells M11˜M14 are connected in series and are arranged in a column, the memory cells M21˜M24 are connected in series and arranged in another column, and the memory cells M31˜M34 are connected in series and are arranged in another column. A plurality of control gate lines CG1˜CG3 is, for example, arranged in parallel and extends in an X direction. The control gate lines CG1˜CG3 connect the control gates of the memory cells of the same column respectively. A plurality of word lines WL1˜WL5 is, for example, arranged in parallel and extends in a Y direction, and connects the select gates of the memory cell of the same column, and the X direction crosses the Y direction. Also, each two neighboring memory cells in the memory cell columns will share a word line.

The structure of the non-volatile memory of the present invention is illustrated below. Herein only the memory cell column consisted of the memory cells M11˜M14 will be illustrated as an example.

Referring to FIGS. 1A, 1B and 1C simultaneously, the non-volatile memory structure of the present invention includes a substrate 200, a plurality of select gate structures 202a˜202e, a plurality of control gates 204a˜204d, a plurality of charge storage layers 206a˜206h, a dielectric layer 208, a dielectric layer 210, a source/drain region (bit line) 212 and a source/drain region (bit line) 214.

The substrate includes, for example, a silicon substrate. The source/drain region (bit line) 212 and the source/drain region (bit line) 214 are disposed in the substrate 200. The source/drain region (bit line) 212 and the source/drain region (bit line) 214 are arranged in parallel and extend in the Y direction. Also, a plurality of isolation structures 201 is, for example, disposed in the substrate 200 and arranged in parallel, and extends in the X direction. The depth d1 of the isolation structure 201 is smaller than the depth d2 of the bit lines BL1, BL2.

A plurality of select gate structures 202a˜202e is, for example, disposed over the substrate 200 between the source/drain region (bit line) 212 and the source/drain region (bit line) 214 respectively. A gap is formed between each two neighboring select gate structures 202a˜202e. Each select gate structure 202a˜202e consists of, for example, a gate dielectric layer 216, a select gate 218, and a cap layer 220, respectively.

The select gates 218 include, for example, doped polysilicon. The gate dielectric layers 216 are, for example, disposed between the select gates 218 and the substrate 200. The gate dielectric layers 216 include, for example, silicon oxide. The cap layers 220 are, for example, disposed over the select gates 218. The cap layers 220 include an insulating material, such as silicon oxide, silicon nitride and the like.

A plurality of control gates 204a˜204d is, for example, disposed in the gaps between two neighboring select gates 202a˜202e respectively. The control gates 204a˜204d are connected in series by the control gate line CG1. Wherein, the control gates 204a˜204d and the control gate line CG1 are, for example, integrally formed, that is, the control gates 204a˜204d extend to the above of the select gates 202a˜202e and are connected with each other to form the control gate line CG1.

A plurality of charge storage layers 206a˜206h is, for example, disposed between the control gates 204a˜204d and the select gate structures 202a˜202e respectively. The material of the charge storage layers 206a˜206h include, for example, conductive material (for example, doped polysilicon) or charge trapping material (for example, silicon nitride). When the charge storage layers 206a˜206h include doped polysilicon, the charge storage layers 206a˜206h are, for example, in a bulk form, and are only located between the control gates 204a˜204d and the select gate structures 202a˜202e. When the material of the charge storage layers 206a˜206h include silicon nitride, the charge storage layers 206a˜206h may be located on the whole sidewalls of the whole select gate structures 202a˜202e as spacers.

The dielectric layers 208 are, for example, disposed between the select gate structures 202a˜202e and the charge storage layers 206a˜206h and between the substrate 200 and the charge storage layers 206a˜206h. The dielectric layers 208 between the select gate structures 202a˜202e and the charge storage layers 206a˜206h function as isolation layers to isolate the select gate structures 202a˜202e and the charge storage layers 206a˜206h. The dielectric layers 208 between the substrate 200 and the charge storage layers 206a˜206h are served as tunneling dielectric layers. The material of the dielectric layers 208 is, for example, silicon oxide.

The dielectric layers 210 are, for example, disposed between the charge storage layers 206a˜206h and the control gates 204a˜204d and between the substrate 200 and the control gates 204a˜204d. The dielectric layers 210 between the charge storage layers 206a˜206h and the control gates 204a˜204d function as isolation layer to isolate the charge storage layers 206a˜206h and the control gates 204a˜204d. The dielectric layers 210 between the substrate 200 and the control gates 204a˜204d function as control gate dielectric layers. The dielectric layers 210 include, for example, silicon oxide.

Two neighboring select gate structures 202a˜202e, the control gate 204a˜204d, between the two neighboring select gate structures 202a˜202e, and the charge storage layer 206a˜206h, respectively constitute a plurality of memory cells M1˜M14. For example, the select gate structures 202a, 202b, the control gate 204a and the charge storage layers 206a, 206b constitute the memory cell M11; the select gate structures 202b, 202c, the control gate 204b and the charge storage layers 206c, 206d constitute the memory cell M12; and so on . . . ; and similarly, the select gate structures 202d, 202e, the control gate 204e and the charge storage layers 206g, 206h, constitute the memory cell M14. The memory cells M11˜M14 are connected with each other without a gap in the X direction (the column direction), and the neighboring memory cells M11˜M14 share the select gate structures 202a˜202e. For example, the memory cells M12 and M11 share the select gate structure 202b, and the memory cells M12 and M13 share the select gate structure 202c.

The charge storage layers 206a˜206h, disposed between the control gates 204a˜204d, and the select gate structures 202a˜202e, respectively, for example, can store one-bit data respectively. Taking the memory cell M11 as an example, the charge storage layer 206a disposed between the control gate 204a and the select gate structure 202a can store one-bit data (left bit), and the charge storage layer 206b disposed between the control gate 204a and the select gate structure 202b may store one-bit data (right bit). Similarly, the memory cells M12˜M14 include two charge storage layers (left bit and left bit) respectively. Therefore, a single memory cell of the non-volatile memory of the present invention can store two-bit data.

There is no gap between the memory cells M1˜M14 in the above non-volatile memory, and the packing density of the memory cell column can thus be promoted. Also, the charge storage layers 206a˜206h, between each select gate structure 202a˜204f and each control gate 204a˜204d, may store one-bit data, that is, a single memory cell of the non-volatile memory of the present invention can store two-bit data.

Furthermore, the gate length of the control gates 204a˜204d, may be determined by the gap length between the select gate structures 202a˜204f. Thus the gate length of the control gates 204a˜204d, can be reduced by reducing the gap length of the select gate structures 202a˜204f, thereby promoting the device packing density.

In the above embodiment, four memory cells M11˜M14 connected in series are illustrated as an example. Of course, in the present invention, the number of the memory cells connected in series may depend on the number actually required. For example, 32 to 64 memory cell structures can be connected in series in a same word line.

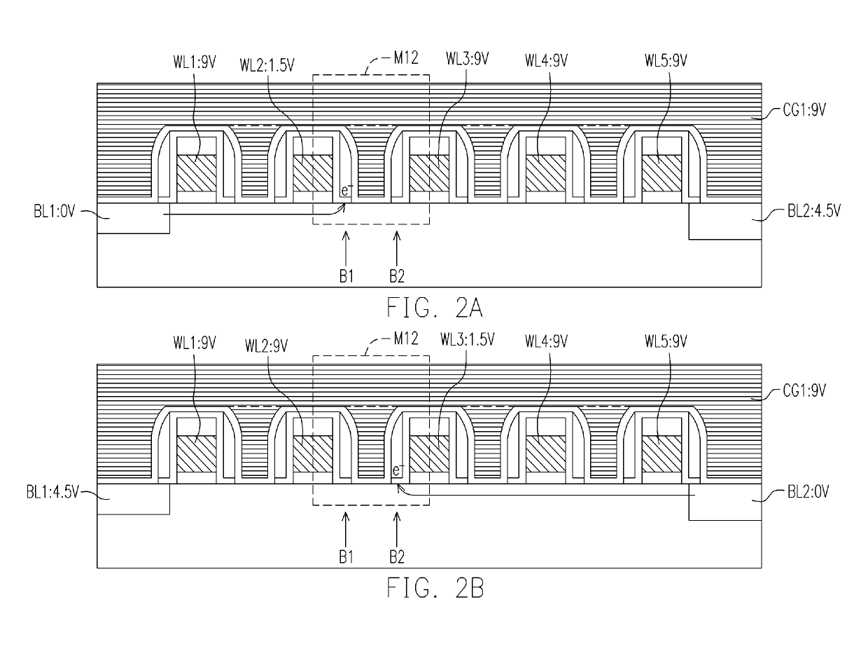

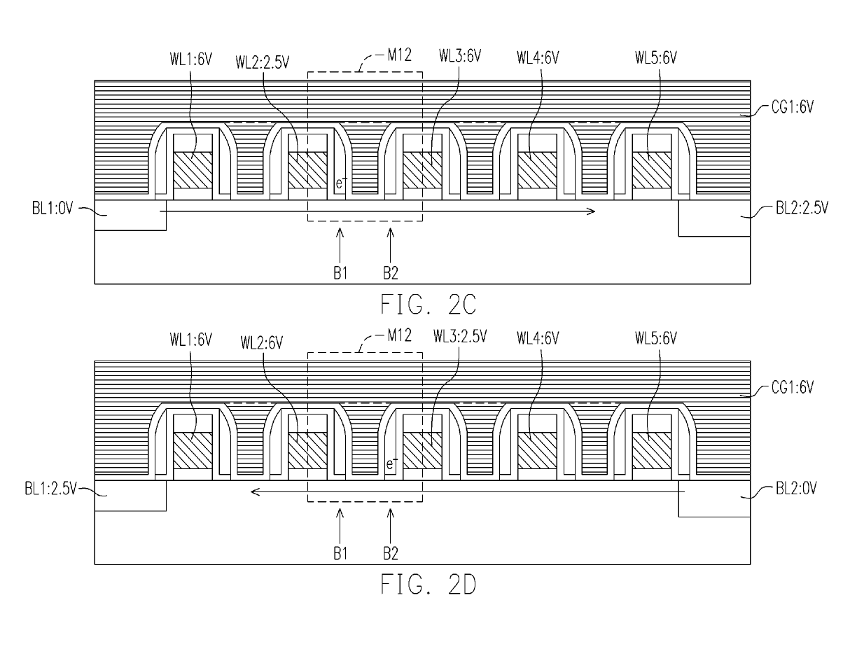

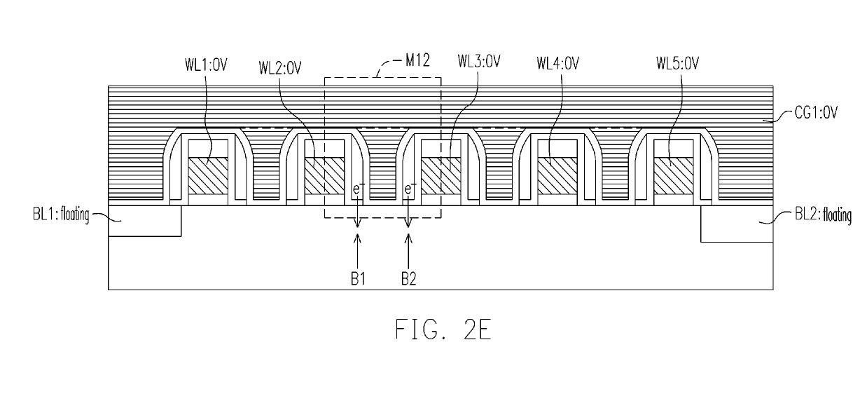

The operation of the memory array of the present invention is illustrated below. FIG. 2A is a schematic view of an example of the programming operation of the non-volatile memory according to the present invention. FIG. 2B is a schematic view of another example of the programming operation of the non-volatile memory according to the present invention. FIG. 2C is a schematic view of an example of the reading operation of the non-volatile memory according to the present invention. FIG. 2D is a schematic view of another example of the reading operation of the non-volatile memory according to the present invention. FIG. 2E is a schematic view of an example of the erasing operation according to the present invention.

The operation of the non-volatile memory of the present invention described herein is only a preferred embodiment is not intended in any way to limit the scope of the present invention. In the following illustration, the memory cell M12 is illustrated as an example.

Referring to FIGS. 1A and 2A simultaneously, in the programming operation, electrons are injected into the charge storage layer B1 (left bit) of the memory cell M12 and stored therein. A voltage Vp1 is applied to the selected control gate line CG1 connected by the selected memory cell M12, wherein the voltage Vp1 is, for example, about 9 Volts. A voltage Vp2 is applied to the bit line BL1 at the side of the charge storage layer B1 (left bit), wherein the voltage Vp2 is, for example, about 0 Volts. A voltage Vp3 is applied to the bit line BL2 at the side of the charge storage layer B2 (right bit), the voltage Vp3 is, for example, about 4.5 Volts. A voltage Vp4 is applied to the selected word line WL2 neighboring the charge storage layer B1 (left bit), wherein the voltage Vp4 is, for example, about 1.5 Volts. A voltage Vp5 is applied to other non-selected word lines WL1, WL3˜WL5, wherein the voltage Vp5 is, for example, about 9 Volts. The above condition would cause the Source-Side Injection (SSI), by which the electrons are injected into the charge storage layer B1 (left bit), thereby programming the left bit of the memory cell M12. In the programming operation, the voltage Vp4 should be higher than or equal to the threshold voltage of the select gate structures; the voltages Vp1, Vp5 should be higher than the threshold voltage of the select gate structures, and higher than the voltage Vp4; and the voltage Vp3 should be higher than the voltage Vp2, so as to perform the programming operation by Source-Side Injection (SSI).

Referring to FIGS. 1A, 2B simultaneously, in the programming operation, when the electrons are stored into the charge storage layer B2 (right bit) of the memory cell M12, a voltage Vp1 is applied to the selected control gate line CG1 connected by the selected memory cell M12, wherein the voltage Vp1 is, for example, about 9 Volts. A voltage Vp2 is applied to the bit line BL2 at the side of the charge storage layer B2 (right bit), wherein the voltage Vp2 is, for example, about 0 Volts. A voltage Vp3 is applied to the bit line BL1 at the side of the charge storage layer B1 (left bit), wherein the voltage Vp3 is, for example, about 4.5 Volts. A voltage Vp4 is applied to the selected word line WL3 neighboring the charge storage layer B2 (right bit), wherein the voltage Vp4 is, for example, about 1.5 Volts. A voltage Vp5 is applied to other non-selected word lines WL1˜WL2, WL4˜WL5, wherein the voltage Vp5 is, for example, about 9 Volts. The above condition would cause the Source-Side Injection (SSI) by which electrons are injected into the charge storage layer B2 (right bit) to program the right bit of the memory cell M12. In such operation, the voltage Vp4 should be higher than or equal to the threshold voltage of the select gate structures; the voltages Vp1, Vp5 should be higher than the threshold voltage of the select gate structures, and higher than the voltage Vp4; and the voltage Vp3 should be higher than the voltage Vp2, so as to carry out the programming operation by Source-Side Injection (SSI).

In the above program operation, as the programming operation is carried out by Source-Side Injection (SSI), the programming speed is higher, and therefore the time required for programming is effectively reduced. Also, as a bi-directional programming method is adopted in the present invention, the program disturbance caused by conventionally used a shared source line can be reduced.

Referring to FIGS. 1A and 2C simultaneously, when reading the memory cell M12, a voltage Vr1 is applied to the selected control gate line CG1 connected to the selected memory cell M12, wherein the voltage Vr1 is, for example, about 6 Volts. A voltage Vr2 is applied to the bit line BL at the side of the charge storage layer B1 (left bit), wherein the voltage Vr2 is, for example, about 0 Volts. A voltage Vr3 is applied to the bit line BL2 at the side of the charge storage layer B2 (right bit), wherein the voltage Vr3 is, for example, about 2.5 Volts. A voltage Vr4 is applied to the selected word line WL2 neighboring the charge storage layer B1 (left bit), the voltage Vr4 is, for example, about 2.5 Volts. A voltage Vr5 is applied to other non-selected word lines WL1, WL3˜WL5, wherein the voltage Vr5 is, for example, about 6 Volts. In such operation, the voltage Vr4 should be higher than or equal to the threshold voltage of the select gate structures; the voltages Vr1, Vr5 should be higher than the threshold voltage of the select gate structures, and higher than the voltage Vr4, to ensure the channel below to be conducted; the voltage Vp3 should be higher than the voltage Vp2. In the meanwhile, when the total charge in the charge storage layer is negative, the channel of the memory cell is turned off and the current is very small, while when the total charge in the charge storage layer is slightly positive, the channel of the memory cell is turned on and the current is large. Accordingly, the state “0” or “1” of the memory cell can be determined based on the on/off status of the channel or by measuring current at the channel of the memory cell.

Referring to FIGS. 1A and 2D simultaneously, when reading the memory cell M12, a voltage Vr1 is applied to the selected control gate line CG1 connected to the selected memory cell M12, wherein the voltage Vr1 is, for example, about 6 Volts. A voltage Vr2 is applied to the bit line BL2 at the side of the charge storage layer B2 (right bit), wherein the voltage Vr2 is, for example, about 0 Volts. A voltage Vr3 is applied to the bit line BL1 at the side of the charge storage layer B1 (left bit), wherein the voltage Vr3 is, for example, about 2.5 Volts. A voltage Vr4 is applied to the selected word line WL3 neighboring the charge storage layer B2 (right bit), wherein the voltage Vr4 is, for example, about 2.5 Volts. A voltage Vr5 is applied to other non-selected word lines WL1˜WL2, WL4˜WL5, wherein the voltage Vr5 is, for example, about 6 Volts. In such operation, the voltage Vr4 should be higher than or equal to the threshold voltage of the select gate structure; the voltages Vr1 and Vr5 should be higher than the threshold voltage of the select gate structures, and higher than the voltage Vr4, to ensure the channel below to be conducted; the voltage Vp3 should be higher than the voltage Vp2. When the total charge in the charge storage layer is negative, the channel of the memory cell is turned off and the current is very small, while when the total charge in the charge storage layer is slightly positive, the channel of the memory cell is turned on and the current is large. Accordingly, the state “0” or “1” of the memory cell can be determined based on the on/off status of the channel or by measuring current at the channel of the memory cell.

Referring to FIGS. 1A and 2E simultaneously, when erasing, a voltage Ve1 is applied to the selected control gate line, a voltage Ve2 is applied to the word lines WL1˜WL5, a voltage Ve3 is applied to the substrate, and the bit lines BL1˜BL2 are made to be floating, such that the electrons stored in the charge storage layer are directed into the substrate, thereby erasing the data in the memory cell. The voltage difference between the voltages Ve1, Ve2 and the voltage Ve3 will cause a channel F-N tunneling effect. The voltage difference between the voltages Ve1, Ve2 and the voltage Ve3 is, for example, about −12 to −20 Volts. For example, the voltages Ve1, Ve2 is 0 Volts, the voltage Ve3 is −12 Volts.

In the non-volatile memory of the present invention, the programming is carried out by Source-Side Injection (SSI) with a unit of a single bit of a single memory cell, and the memory cell is erased using the FN tunneling effect. Therefore, the electron injection efficiency is higher, the operating current of the memory cell current is lower and the operating speed is higher. Thus, the overall power consumption is effectively reduced.

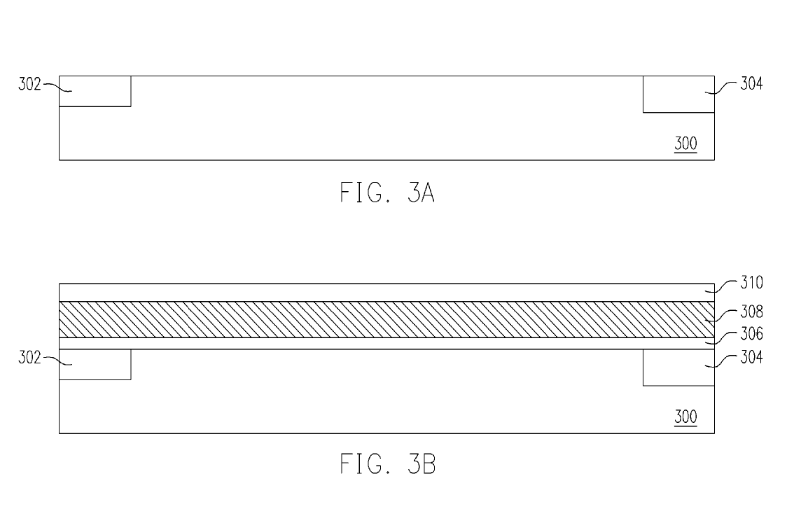

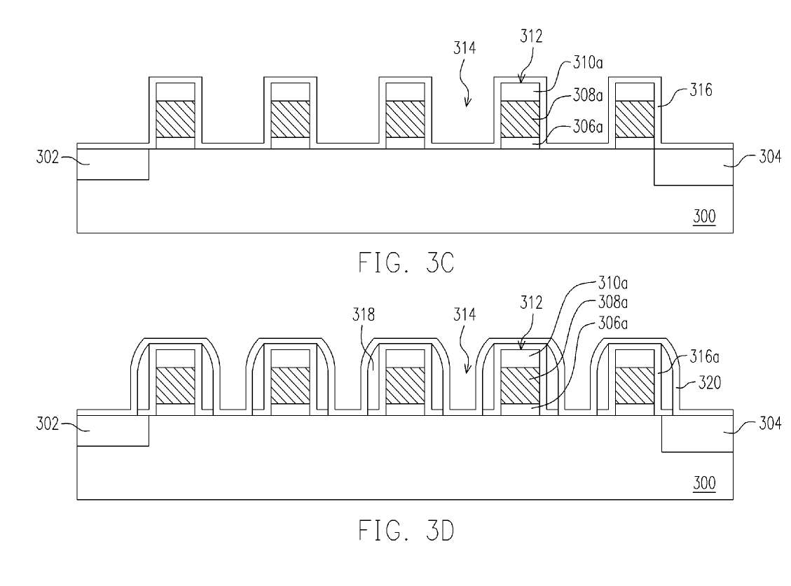

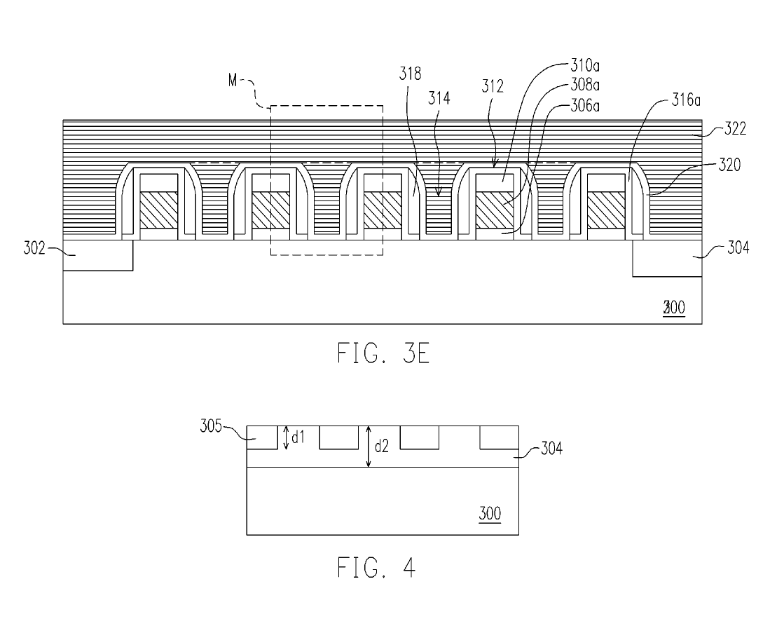

The method of fabricating the non-volatile memory of the present invention is illustrated below. FIGS. 3A to 3E show a sectional flow chart of manufacturing the non-volatile memory according to a preferred embodiment of the present invention. FIGS. 3A to 3E show a sectional view along line A-A′ in FIG. 1A. FIG. 4 shows a structural sectional view along line B-B′ in FIG. 1A.

Referring to FIG. 3A, a substrate 300 is provided, wherein the substrate 300 is, for example, a silicon substrate. A doped region 302 and a doped region 304 are formed in the substrate 300. The doped regions 302, 304 are arranged in parallel and, for example, extend in a first direction. The step of forming the doped regions 302 and 304 includes, for example, forming a mask layer (not shown) over the substrate 300; carrying out the ion implantation process to form the doped regions 302, 304 in the substrate 300; and removing the mask layer. Next, as shown in FIG. 4, isolation structures 305 are formed in the substrate 300, the isolation structures 305, for example, are arranged in parallel, and extend in a second direction, which crosses the first direction. The depth d1 of isolation structures 305 is, for example, smaller than the depth d2 of the doped region 302 and the doped region 304.

Next, referring to FIG. 3B, a dielectric layer 306, a conductive layer 308 and a cap layer 310 are sequentially formed over the substrate 300. The dielectric layer 306 includes, for example, silicon oxide, and the dielectric layer 306 is formed, for example, by a thermal oxidation. The conductive layer 308 includes, for example, doped polysilicon, and the conductive layer 308 is formed, for example, by carrying out an ion implantation after a non-doped polysilicon layer is formed by using the chemical vapor deposition or in situ implantation of dopant during chemical vapor deposition. The material of the cap layer 310 includes, for example, silicon oxide, wherein the cap layer 310 is formed, for example, by a chemical vapor deposition process.

Referring to FIG. 3C, the cap layer 310, the conductive layer 308 and the dielectric layer 306 are patterned to form a plurality of select gate structures 312. The select gate structures 312 are disposed between the doped region 302 and the doped region 304, and they are arranged in parallel, and for example, extend in a first direction. The cap layer 310, the conductive layer 308 and the dielectric layer 306 are patterned, for example, by performing lithography and etching process. The select gate structure 312 is includes, for example, a cap layer 310a, a conductive layer 308a and dielectric layer 306a respectively. A gap 314, for example, is formed between each two neighboring select gate structures 312. The conductive layers 308a, for example, function as a select gate, and the dielectric layers 306a, for example, function as a select gate dielectric layer.

Next, another dielectric layer 316 is formed over the substrate 300, covering the select gate structures 312. The material of the dielectric layer 316 is, for example, silicon oxide. The dielectric layer 316 is formed by, for example, the thermal oxidation or chemical vapor deposition.

Referring to FIG. 3D, charge storage layers 318 are formed on the sidewalls of the select gate structures 312. The material of the charge storage layers 318 includes conductive material (for example, doped polysilicon) or charge trapping material (for example, silicon nitride). The charge storage layers 318 are formed, for example, by performing an anisotropic etching process after forming a charge storage material layer. During the step of forming the charge storage layers 318, a portion of the dielectric layer 316 is removed until the substrate 300 is exposed to form the dielectric layers 31 6a. The dielectric layers 316a are disposed, for example, between the charge storage layers 318 and the select gate structure 312 and between the charge storage layers 318 and the substrate 300. The dielectric layers 316a between the charge storage layers 318 and the select gate structures 312 function as an isolation layer to isolate the charge storage layers 318 and the select gate structures 312. The dielectric layers 316a between the charge storage layers 318 and the substrate 300 function as a tunneling dielectric layer.

Next, another dielectric layer 320 is formed over the substrate 300, covering the select gate structures 312 and the charge storage layers 318. The dielectric layers 320 include, for example, silicon oxide. The dielectric layer 320 is formed, for example, by a thermal oxidation or chemical vapor deposition process.

Referring to FIG. 3E, a plurality of conductive layers 322 are formed on the substrate 300, the conductive layers 322 fill the gaps between the select gate structures 312. Also, the conductive layers 322 are arranged in parallel and extend in a second direction, which crosses the first direction. The conductive layers 322 function as a control gate line. The step of forming the conductive layers 322 (control gate lines) include, for example, forming a conductive material layer over the substrate 300; performing a planarization process using a chemical mechanical polishing or etch back process; and patterning the conductive material layer to form a plurality of conductive layers 322 (control gate lines). The conductive layers 322 include, for example, doped polysilicon, wherein the conductive layers 322 are formed, for example, by forming a non-doped polysilicon layer using the chemical vapor deposition process and implanting dopants into the non doped polysilicon layer or in situ implantation of dopants during the chemical vapor deposition process of forming the polysilicon layer. If the material of the charge storage layers 318 includes a conductive material (for example, doped polysilicon), the step of patterning the conductive material layer to form the conductive layers 322 further includes a step of removing a portion of the charge storage layers 318 to pattern the charge storage layer 318 into blocks such that the charge storage layers 318 are located between the conductive layers 322 and the select gate structures 312. If the material of the charge storage layers 318 include the charge trapping material (for example, silicon nitride), the step of patterning the charge storage layers 318 may be omitted.

between the charge storage layers 318 and the conductive layers 322 function as an isolation layer to isolate the charge storage layers 318 and the conductive layers 322. The dielectric layers 320 between the substrate 300 and the conductive layers 322 function as a control gate dielectric layer.

Two neighboring select gate structures 312, the conductive layer 322 between the two neighboring select gate structures 312 and the charge storage layers 318 constitute a plurality of memory cells M respectively. The memory cells M are connected in series without a gap, and the neighboring memory cells M share a select gate structure 312. The subsequent process of the memory array is well known to those skilled in the art, and will not be described hereinafter.

In the above embodiment, as the memory cells are connected in series without a gap, the packing density of the memory array can be promoted. Also, the step of forming the non-volatile memory of the present invention is comparatively simpler than the conventional process, and the fabrication cost can be thus reduced.

Furthermore, in the above embodiment, only four memory cells are used for illustrating the embodiments of the present invention. Of course, any number of memory cells may be formed as required by using the method of fabricating the non-volatile memory of the present invention, for example, 32 to 64 memory cell structures may be connected in series on a single word line. Also, the method of fabricating the memory cell column of the present invention may be applied to form an entire memory array.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate, having at least two bit lines arranged in parallel and extended along a first direction;
a plurality of select gate structures, disposed over the substrate between the two bit lines respectively, arranged in parallel and extended along the first direction, wherein a gap is formed between two adjacent select gate structures;
a plurality of control gate lines, each disposed in the gap between every two adjacent select gate structures respectively, wherein the control gate lines are arranged in parallel and extended along a second direction, which crosses the first direction; and
a plurality of charge storage layers, disposed between the select gate structures and the control gate lines respectively.

2. The non-volatile memory of claim 1, wherein the material of the charge storage layers comprises silicon nitride or doped polysilicon.

3. The non-volatile memory of claim 1, further comprising a first dielectric layer disposed between the charge storage layers and the control gate lines respectively.

4. The non-volatile memory of claim 3, wherein the first dielectric layers comprise silicon oxide.

5. The non-volatile memory of claim 1, further comprising a tunneling dielectric layer disposed between the charge storage layers and the substrate respectively.

6. The non-volatile memory of claim 5, wherein the tunneling dielectric layers comprises silicon oxide.

7. The non-volatile memory of claim 1, further comprising a second dielectric layer disposed between the charge storage layers and the select gate structures respectively.

8. The non-volatile memory of claim 7, wherein the second dielectric layer comprises silicon oxide.

9. The non-volatile memory of claim 1, further comprising a plurality of isolation structures extending in the second direction disposed in the substrate between the control gate lines.

10. The non-volatile memory of claim 9, wherein a depth of the isolation structures is less than a depth of the two bit lines.

11. The non-volatile memory of claim 1, wherein each of the select gate structures comprises:
a gate dielectric layer, disposed over the substrate;
a select gate, disposed over the gate dielectric layer; and
a cap layer, disposed over the select gate.

12. The non-volatile memory of claim 1, further comprising a control gate dielectric layer disposed between the control gate lines and the substrate.

13. A method of fabricating the non-volatile memory, comprising:
providing a substrate;
forming at least two doped regions in the substrate, wherein the two doped regions are arranged in parallel and extend along a first direction;
forming a plurality of select gate structures over the substrate between the two doped regions, the select gate structures are arranged in parallel and extend along the first direction, and a gap is formed between every two neighboring select gate structures;
forming a first dielectric layer over the substrate;
forming a plurality of spacers on the sidewalls of the select gate structures, wherein the material of spacers comprises charge storage material;
forming a second dielectric layer over the substrate; and
forming a plurality of control gate lines over the substrate, wherein the control gate lines fill the gaps, and are arranged in parallel and extended along a second direction crossing the first direction.

14. The method of claim 13, further comprising a step of forming a plurality of isolation structures in the substrate extending along the second direction after the step of forming the two doped regions in the substrate, wherein a depth of the isolation structures is less than a depth of the two doped regions.

15. The method of claim 13, wherein the step of forming the select gate structures over the substrate comprises:
forming a gate dielectric layer over the substrate;
forming a first conductive layer over the gate dielectric layer;
forming a cap layer over the first conductive layer; and
patterning the cap layer, the first conductive layer and the gate dielectric layer.

16. The method of claim 13, wherein the spacers comprise silicon nitride.

17. The method of claim 13, wherein the first and second dielectric layers comprise silicon oxide.

18. The method of claim 13, wherein the step of forming the control gate lines over the substrate comprises:
forming a second conductive layer over the substrate; and
patterning the second conductive layer.

19. The method of claim 18, further comprises a step of removing a portion of the spacers to form a plurality of charge storage blocks in the step of patterning the second conductive layer.

20. The method of claim 19, wherein the charge storage blocks comprises silicon nitride or doped polysilicon.

21. A method of operating a non-volatile memory, for the non-volatile memory comprising a memory array having at least a first bit line and a second bit line, disposed in parallel in a substrate and extended in a row direction; a plurality of select gate structures, disposed in parallel on the substrate between the first bit line and the second bit line and extended in the row direction, a gap formed between each two neighboring select gate structures respectively; a plurality of control gates, disposed on the substrate filling the gaps between two neighboring select gate structures; a plurality of charge storage layers, disposed between the select gate structures and the control gate line respectively; a plurality of word lines, arranged in parallel in the row direction and connected the gates of the select gate structures of the same row; a plurality of control gate lines, disposed in parallel on the substrate and extended in the column direction, and connecting the control gates of the same column; wherein two adjacent select gate structures, the control gates between two adjacent select gate structures, two charge storage layers between the select gate structures and the control gates respectively constitute a plurality of memory cells, and the adjacent memory cells share a select gate structure; the charge storage layer of each memory cell includes a first bit at the first bit line side, and a second bit at the second bit line side; the method comprising:
performing a programming operation to the non-volatile memory by applying a first voltage to a selected control gate line connected to a selected memory cell; applying a second voltage to the first bit line; applying a third voltage to the second bit line; applying a fourth voltage to a first selected word line at the first bit line side of the selected memory cell; and applying a fifth voltage to other non-selected word lines, wherein the fourth voltage is higher than or equal to a threshold voltage of the select gate structures, the first and fifth voltages are higher than the fourth voltage, the third voltage is higher than the second voltage, so as to program the first bit by Source-Side Injection (SSI).

22. The method of operating the non-volatile memory of claim 21, wherein the first voltage is about 7 volts, the second voltage is about 0 Volts, the third voltage is about 4.5 Volts, the fourth voltage is about 1.5 Volts and the fifth voltage is about 7 Volts.

23. The method of operating the non-volatile memory of claim 21, further comprising performing a programming operation to the non-volatile memory by applying a sixth voltage to a selected control gate line connected to a selected memory cell; applying a seventh voltage to the second bit line; applying a eighth voltage to the first bit line; applying a ninth voltage to a second selected word line at the second bit line side of the selected memory cell; and applying a tenth voltage to other non-selected word lines, wherein the ninth voltage is higher than or equal to a threshold voltage of the select gate structures, the sixth and tenth voltages are higher than the ninth voltage, and the eighth voltage is higher than the seventh voltage, as so to program the second bit by Source-Side Injection (SSI).

24. The method of operating the non-volatile memory of claim 23, wherein the sixth voltage is about 7 Volts, the seventh voltage is about 0 Volts, the eighth voltage is about 4.5 Volts, the ninth voltage is about 1.5 Volts and the tenth voltage is about 7 Volts.

25. The method of operating the non-volatile memory of claim 21, further comprising performing an erasing operation to the non-volatile memory by applying an eleventh voltage to the control gate lines; applying a twelfth voltage to the word lines; applying a thirteenth voltage to the substrate; and floating the bit lines such that the electrons stored in the charge storage layers are injected into the substrate, wherein a voltage difference between the eleventh, twelfth voltages, and the thirteenth voltage cause FN tunneling effect.

26. The method of operating the non-volatile memory of claim 25, wherein the voltage difference is about −12 to −20 Volts.

27. The method of operating the non-volatile memory of claim 25, wherein the eleventh voltage is 0 Volts, the twelfth voltage is 0 Volts, and the thirteenth voltage is 12 Volts.

28. The method of operating the non-volatile memory of claim 21, further comprising performing a read operation to the non-volatile memory by applying a fourteenth voltage to a selected control gate line connected to a selected memory cell; applying a fifteenth voltage to the first bit line; applying a sixteenth voltage to the second bit line; applying a seventeenth voltage to the first selected word line at the first bit line side of the selected memory cell; and applying an eighteenth voltage to other non-selected word lines, wherein to read the first bit, the seventeenth voltage is higher than a threshold voltage of the select gate structures, the fourteenth and eighteenth voltages are higher than the seventeenth voltage, and the fifteenth voltage is higher than the sixteenth voltage.

29. The method of operating the non-volatile memory of claim 28, wherein the fourteenth voltage is about 5 Volts, the fifteenth voltage is about 2.5 Volts, the sixteenth voltage is about 0 Volts, the seventeenth voltage is about 2.5 Volts and the eighteenth voltage is about 5 Volts.

30. The method of operating the non-volatile memory of claim 21, further comprising performing a read operation to the non-volatile memory by applying a nineteenth voltage to a selected control gate line connected to a selected memory cell; applying a twentieth voltage to the second bit line; applying a twenty-first voltage to the first bit line; applying a twenty-second voltage to the second selected word line at the second bit line side of the selected memory cell; applying a twenty-third voltage to other non-selected word lines, wherein to read the second bit, the twenty-second voltage is higher than a threshold voltage of the select gate structures, the nineteenth and twenty-third voltages are higher than the twenty-second voltage and the twentieth voltage is higher than the twenty-first voltage.

31. The method of operating the non-volatile memory of claim 30, wherein the nineteenth voltage is about 5 Volts, the twentieth voltage is about 2.5 Volts, the twenty-first voltage is about 0 Volts, the twenty-second voltage is about 2.5 Volts, and the twenty-third voltage is about 5 Volts.
